(19) United States
(12) Patent Application Publication
(10) Pub. No.: US 2010/0259497 A1
(43) Pub. Date: Oct. 14, 2010

(54) INTEGRATED TOUCH SENSOR ELECTRODE AND BACKLIGHT MASK

(75) Inventors: Andrew Livingston, North Aurora, IL (US); Mark Burleson, Aurora, IL (US); Deron Stambaugh, Waterman, IL (US)

Correspondence Address: BARNES & THORNBURG LLP, P.O. BOX 2786, CHICAGO, IL, 60690-2786, US

(73) Assignee: TOUCHSENSOR TECHNOLOGIES, LLC, Wheaton, IL (US)

(21) Appl. No.: 12/757,503

(22) Filed: Apr. 9, 2010

Related U.S. Application Data
(60) Provisional application No. 61/168,152, filed on Apr. 9, 2009.

(51) Int. Cl. G06F 3/041; H05K 3/00

(52) U.S. Cl. 345/173; 216/13

(57) ABSTRACT

A user interface includes a user interface substrate and an associated integrated sensing electrode and backlight mask in the form of an opaque material having an aperture or otherwise light-transmissive portion therein. The integrated sensing electrode and backlight mask is positioned between the user interface substrate and a light source, such that indicia in the form of the aperture is visible at a surface of the user interface substrate when the light source is illuminated.

### CROSS-REFERENCE TO RELATED APPLICATIONS

This application claims priority from and incorporates by reference the disclosure of U.S. Provisional Patent Application No. 61/168,152, filed on Apr. 9, 2009.

### BACKGROUND OF THE INVENTION

Controlled devices, for example, automobiles, home appliances, consumer electronics, industrial machinery, and the like, can include one or more local or remote user interfaces through which a user can interact with the device. Such user interfaces can include displays providing information about the device and switching means that can be actuated by a user to control the device or a function thereof. Such switching means often are embodied as electronic sensors, for example, field effect sensors or capacitive sensors. Such sensors typically include one or more sensing electrodes and control circuitry for operating the sensors.

User interfaces using such electronic sensors (sometimes referred to herein as touch sensors) can include a user interface substrate having one or more operable touch surfaces through which the user interacts with the controlled device and a touch sensor substrate bearing one or more corresponding touch sensors attached to the user interface panel. Such user interface substrates can be embodied as glass or plastic panels, and such touch sensor substrates can be embodied as printed wiring boards or flexible circuit carriers attached to a surface of the user interface substrate.

Such touch sensor substrates can bear a number of touch sensors, each including one or more sensing electrodes. Such user interface substrates can include some form of indicia, for example, words or symbols, in proximity to each touch sensor for identifying the touch sensor's location and/or function. The indicia can overlie the respective touch sensors' sensing electrode(s), thereby positively identifying their locations. The indicia can be etched, screened, printed, or otherwise formed or disposed on the user interface substrate.

Such user interfaces can include backlighting that illuminates selected portions of the user interface panel, for example, the indicia identifying the various touch sensors, using a light source located behind the user interface substrate. Some user interfaces use backlighting and backlight masks (typically in the form of dark frit or decorative ink on the user interface substrate), instead of (or in addition to) decoration on the user interface substrate to define the indicia. In such embodiments, the indicia typically appear as illuminated portions of the user interface substrate (provided by the backlighting) against a dark background (provided by the backlight mask). Alternatively, the indicia can appear to the user as dark portions of the user interface substrate (provided by the backlight mask) against an illuminated background (provided by the backlighting).

Frit and decorative ink typically are not completely opaque. As such, backlight masks made of frit and/or decorative ink can allow some light to bleed there through and thereby into and through portions of the user interface substrate that are intended to appear opaque. As such, the contrast between the indicia and the background can be less than ideal, with the indicia appearing less distinctly than desired, particularly when the indicia are relatively small.

### BRIEF DESCRIPTION OF THE DRAWINGS

FIG. 1 is a plan view of an illustrative embodiment of a user interface substrate 12 showing a user interface substrate 12 as it might be viewed by a user, which user interface substrate 12 defines operative touch surfaces 14 corresponding to touch sensors 16 associated with the other side of user interface substrate 12 and which also defines areas corresponding to indicators 18 and indicia 20;

FIG. 2 is a cross-sectional side view of an illustrative embodiment of a user interface 10 including user interface substrate 12, circuit carrier 24 associated with the rear surface of user interface substrate 12, touch sensor sensing electrodes 16 and masks 22 disposed on a rear surface of circuit carrier 24, and lighting substrate 28, light sources 30, and light guides 26 associated with circuit carrier 24, sensing electrodes 16 and masks 22;

FIG. 3 is a cross-sectional side view of another illustrative embodiment of a user interface 10 including user interface substrate 12, circuit carrier 24 associated with the rear surface of user interface substrate 12, touch sensor sensing electrodes 16 and masks 22 disposed on a front surface of circuit carrier 24, and lighting substrate 28, light sources 30, and light guides 26 associated with circuit carrier 24, sensing electrodes 16 and masks 22;

FIG. 4 is a cross-sectional side view of yet another illustrative embodiment of a user interface 10 including user interface substrate 12, circuit carrier 24 associated with the rear surface of user interface substrate 12, touch sensor sensing electrodes 16 and masks 22 disposed on a front surface of circuit carrier 24, and light sources 30 and reflectors 32 associated with circuit carrier 24, sensing electrodes 16 and masks 22; and

FIG. 5 is a plan view of a rear surface of a circuit carrier 24 bearing touch sensor sensing electrodes 16, masks 22, electrical traces 34, and bonding pads 36.

### DETAILED DESCRIPTION OF THE ILLUSTRATED EMBODIMENTS

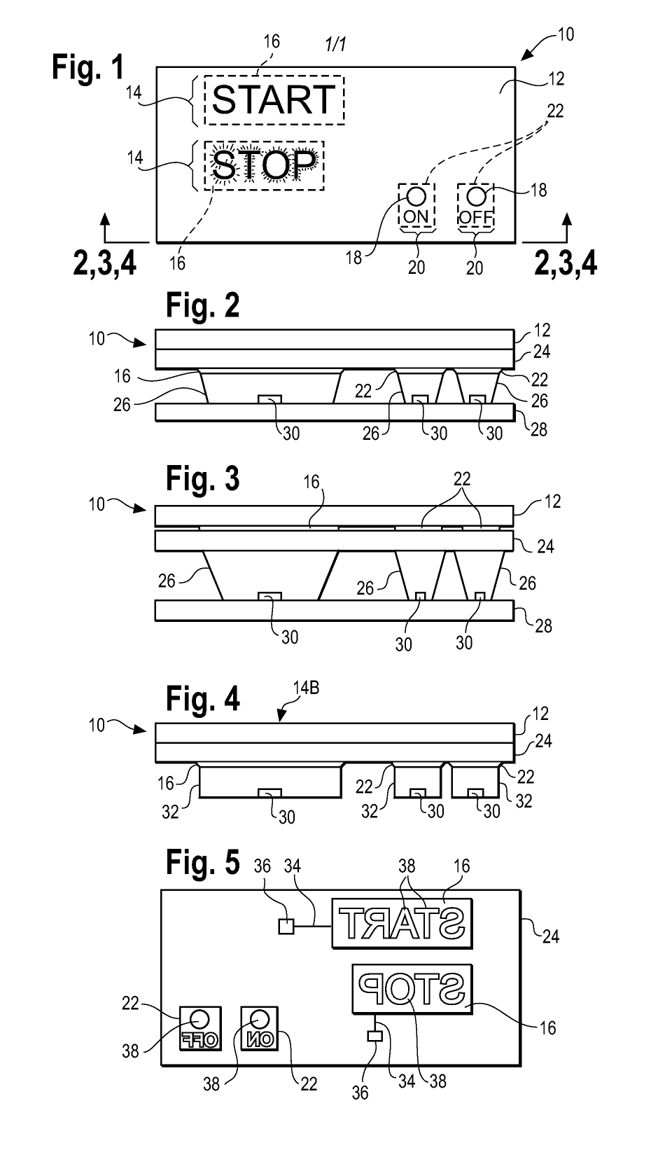

FIG. 1 illustrates an embodiment of a user interface 10 as it might appear to a user. More particularly, FIG. 1 shows a front or other user-oriented surface of a user interface substrate 12 defining touch surfaces 14. Touch surfaces 14 correspond, respectively, to touch sensor sensing electrodes 16 (shown in phantom) associated with the other side of user interface substrate 12. Each sensing electrode 16 can form a portion of a corresponding touch sensor that can be actuated by touch or proximity of a stimulus, for example, a user's finger or other object, to the respective touch surface 14, as would be understood by one skilled in the art and as discussed further below.

FIG. 1 shows indicia in the form of the words “START” and “STOP” in the areas of user interface surface 12 corresponding to touch surfaces 14. These indicia are defined by light-transmissive portions, for example, apertures, in corresponding sensing electrodes 16 associated with the other side of user interface surface 12. These indicia can be selectively illuminated by backlighting, as discussed further below. These indicia can, but need not, be generally visible to a user when the corresponding backlighting is not energized. For example, with the corresponding backlighting de-energized, the indicia could appear dark, opaque or otherwise generally take on the appearance of surrounding portions of the surface of user interface substrate 12.

User interface 10 also includes indicators 18 and corresponding indicia 20, both of which are visible from the front surface of user interface substrate 12. Indicator 18 and indicia 20 are defined by corresponding masks 22 (shown in phantom) associated with the other side of user interface substrate 12. Indicators 18 and/or indicia 20 can be selectively illuminated by backlighting, as discussed further below. Indicators 18 and/or indicia 20 can, but need not be, generally visible to a user when the corresponding backlighting is not energized. For example, with the corresponding backlighting de-energized, indicators 18 and/or indicia 20 can appear dark, opaque or otherwise generally take on the appearance of surrounding portions of the surface of user interface substrate 12.

The forms of touch surfaces 14 as shown in the drawings are merely illustrative. In other embodiments, touch surfaces could take other forms, for example, round or square, and they could be located elsewhere with respect to user interface substrate 12, indicators 18 and indicia 20. Similarly, the forms of indicia 20 and the indicia corresponding to surfaces 14 as shown in the drawings are merely illustrative. In other embodiments, these indicia could take other forms, for example, one or more other words, letters, numbers, or symbols. Alternatively, the indicia could be omitted Likewise, the forms of indicators 18 shown in the drawings are merely illustrative. In other embodiments, indicators 18 could be of other sizes and shapes, and they could be located elsewhere with respect to indicia 20. Alternatively, indicators 18 could be omitted.

FIG. 2 illustrates an embodiment of a user interface 10 in cross-section. More particularly, FIG. 2 shows user interface substrate 12, circuit carrier 24 associated with the rear surface of user interface substrate 12, and sensing electrodes 16 and masks 22 disposed on the rear surface of circuit carrier 24. FIG. 2 also shows a lighting substrate 28 bearing light sources 30 and light guides 26 optically coupling light sources 30 to corresponding ones of sensing electrodes 16 and masks 22.

User interface substrate 12 could be made of any suitable material, for example, glass or plastic, as would be recognized by one skilled in the art. At least the portions of user interface substrate 12 corresponding to indicators 18, indicia 20, and the indicia corresponding to touch surfaces 14 should be sufficiently transparent or translucent to allow light from light sources 30 to be visible at the user-oriented surface of user interface substrate 12. Other portions of user interface substrate 12 could, but need not, be generally opaque or otherwise not generally transparent or translucent, or they could be rendered as such by means of dark ink, frit, or an overlay having generally opaque or non-light-transmissive portions (not shown) applied to either surface thereof. Preferably, the user-oriented surface of user interface substrate 12 has a dead front or dark appearance that provides substantial contrast to the light emanating from associated backlight units, as will be discussed further below.

Circuit carrier 24 could be any suitable form of rigid or flexible circuit carrier, as would be recognized by one skilled in the art. For example, circuit carrier 24 could be embodied as a rigid substrate, such as a printed wiring board made of FR4 or other suitable material. In other embodiments, circuit carrier 24 could be a flexible circuit carrier made of polyester or other suitable material. Portions of circuit carrier 24 corresponding to sensor electrodes 16 and masks 22 (or, more particularly, the apertures or otherwise light-transmissive portions thereof) should be transparent, translucent or otherwise sufficiently light-transmissive to allow light from light sources 30 to pass there through. Other portions of circuit carrier 24 could, but need not, be similarly light transmissive. Alternatively, such other portions could be generally opaque or rendered as such by a coating, overlay, or otherwise.

Circuit carrier 24 could be attached to user interface substrate 12 in any suitable manner. For example, circuit carrier 24 could be attached to user interface substrate 12 using adhesives, mechanical fasteners, snap-fit structures, and/or other means, as would be recognized by one skilled in the art.

As illustrated in FIG. 5, sensing electrodes 16 include apertures 38 through which light can pass. Apertures 38 collectively correspond to and define the indicia visible at the front surface of user interface substrate 12 in the regions of touch surfaces 14. Similarly, masks 22 include apertures 38 defining indicators 18 and indicia 20. FIGS. 1 and 5 depict sensing electrodes 16 and masks 22 as generally rectangular. In other embodiments, sensing electrodes 16 and masks 22 can be square, round, or have any other regular or irregular shape.

Preferably, sensing electrodes 16 and masks 22 are made of a substantially opaque material. In other embodiments, sensing electrodes 16 and masks 22 could be made of material that is less than substantially opaque, that is, material that is somewhat light transmissive. In certain embodiments, sensing electrodes 16 could be made of a substantially opaque conductive material defining apertures 38 therein, and could further include a substantially transparent conductive material (not shown) at least in the area of apertures 38, that is, superimposed with apertures 38. Such a substantially transparent conductive material could be disposed upon or underneath, and be electrically coupled to, the substantially opaque conductive material. Such transparent conductive material could effectively increase the surface area of sensing electrodes 16 and potentially improve their performance, while not adversely affecting their ability to transmit light through apertures 38 and thereby define the indicia to be visible at touch surfaces 14.

Sensing electrodes 16 could be disposed on circuit carrier 24 in any suitable manner. For example, circuit carrier 24 could be plated or otherwise coated with conductive material, such as copper or aluminum, and then patterned and etched to yield sensing electrodes 16 and masks 22. Such conductive material also could be patterned and etched to form other circuitry, including without limitation electrical traces 34 and bonding pads 36 that might be needed for the construction and operation of touch sensors associated with sensing electrodes 16 and/or other elements of user interface 10. Alternatively, sensing electrodes 16, masks 22 and/or additional circuitry could be disposed on circuit carrier 24 by sputtering, application of conductive ink, or other techniques, as would be recognized by one skilled in the art. In other embodiments, masks 22 could be made of any suitable non-conductive material applied to circuit carrier 24 in any suitable manner.

Sensing electrodes 16 could form part of any suitable type of touch sensor that can be actuated by proximity or touch of a user's finger or other object, as would be recognized by one skilled in the art. For example, sensing electrodes 16 could be coupled to a TS-100 ASIC available from TouchSensor Technologies, LLC of Wheaton, Ill. to form a touch sensor as described in U.S. Pat. No. 6,320,282 and related patents and applications. Alternatively, sensing electrodes 16 could be coupled to control circuitry to form touch sensors such as those disclosed in U.S. Pat. Nos. 5,594,222 and 6,310,611. U.S. Pat. Nos. 5,594,222 and 6,320,282 disclose touch sensors having active components in close proximity to one or more sensing electrodes. In other embodiments, sensing electrodes 16 could be coupled to control circuitry to form capacitive touch sensors as would be recognized by one skilled in the art. In any of the foregoing embodiments, the touch sensor control circuitry could be disposed on the same (or other) side of the same carrier or substrate as sensing electrodes 16 and/or masks 22.

Sensing electrodes 16 and masks 22 are shown in the drawings as being disposed on circuit carrier 24, which in turn is attached to user interface substrate 12. Alternatively, sensing electrodes 16 and/or masks 22 could be at least partially embedded within circuit carrier 24. In other embodiments, sensing electrodes 16 and/or masks 22 could be disposed directly onto user interface substrate 12 or at least partially embedded within user interface substrate 12. In such embodiments, additional circuitry that might be used for the construction or operation of touch sensors corresponding to sensing electrodes 16 or other portions of user interface 10 also could be similarly disposed on user interface substrate 12 and circuit carrier 24 could be omitted. Alternatively circuit carrier 24 could be retained to, for example, carry other circuitry, lighting elements or the like. In further embodiments, touch surfaces 14 could be defined by circuit carrier 24 or an overlay (for example, a decorative overlay) thereon. In such embodiments, circuit carrier 24 could function as a user interface substrate, and user interface substrate 12 could be omitted as a separate structure.

Masks 22 are shown in the drawings as defining apertures 38 corresponding to both indicators 18 and indicia 20. In other embodiments, individual masks 22 could be used to define indicators 18 and indicia 20.

Lighting substrate 28 can be made of any suitable material and can be attached to, for example, circuit carrier 24 or user interface substrate 12 by any suitable means, including adhesives, snap-fit structures, stand-offs, mechanical fasteners, and the like, as would be recognized by one skilled in the art. Light guides 26 can be integral with lighting substrate 28 or they can be discrete components attached to lighting substrate 28. Light sources 30 can be any suitable form of light source, for example, LEDs, lamps, and the like, as would be recognized by one skilled in the art. Light sources 30 can be disposed on and powered from lighting substrate 28.

Preferably, light guides 26 abut circuit carrier 24 and/or sensing electrodes 16 and masks 22 thereon and/or intermediate, substantially light-tight gaskets (not shown) so as to substantially direct/contain light emanating from corresponding light source 30 to the respective electrode 16 or mask 22 and preclude spread of light emanating from such light source 30 to surrounding regions of circuit carrier 24, user interface substrate 12, and/or the environment generally. Light guides could be made of any suitable material, for example, an inherently reflective material. In other embodiments, light guides 26 could be coated with a reflective material.

FIG. 3 is side view of another embodiment of user interface 10. This embodiment is similar to the FIGS. 1 and 2 embodiment but differs in that sensing electrodes 16 and masks 22 are disposed on the front surface of circuit carrier 24, rather than the rear surface thereof. In other embodiments, sensing electrodes 16 and/or masks 22 could be disposed on both surfaces of circuit carrier 24.

FIG. 4 is a side view of a further embodiment of user interface 10. This embodiment is similar to the FIGS. 1 and 2 embodiment but differs with respect to the backlighting structure. More particularly, this embodiment omits the backlighting structure of the FIGS. 1 and 2 embodiment and includes in its place a light source 30 and reflector 32 in association with each of sensing electrodes 16 and masks 22. In this embodiment, light sources 30 could be disposed on and powered from circuit carrier 24. In an alternate embodiment wherein sensing electrodes 16 are disposed directly on user interface substrate, light sources 30 could be disposed on and powered from user interface substrate 12, as well.

Optical filters and/or diffusers (not shown) can be associated with user interface 10 to condition or color the light emanating from light sources 30. For example, a filter layer (not shown) could be located between user interface substrate 10 and circuit carrier 24 to convert, for example, white light emanating from light sources 30 to red, green, yellow or other colored light. A diffuser layer could be similarly located.

Also, user interface 10 could further include other elements, for example, other sensors, switches, displays, indicia, and the like.

In operation, light sources 30 can be selectively illuminated. Light emanating from light sources 30 is directed (and can be reflected or diffused) by light guides 26 or reflector 32 toward sensing electrodes 16 and/or masks 22. This light can continue through apertures 38 and to the user-oriented surface of user interface substrate 12, but is substantially blocked or attenuated by the portions of sensing electrodes and/or masks 22 surrounding apertures. This light thereby appears at the user-oriented surface of user interface substrate 12 in the form of indicators 18, indicia 20, and/or the indicia corresponding to touch surfaces 14.

User interface 10 can be made by plating or otherwise coating circuit carrier 24 with one or more layers of substantially opaque conductive material, for example, copper, on either or both sides of the circuit carrier. This substantially opaque conductive material can be patterned and etched to form touch sensor sensing electrodes 16 and/or masks 22, including the apertures therein corresponding to indicators 18, indicia 20, and the indicia defined by sensing electrodes 16. This substantially opaque conductive material can be further patterned and etched to form electrical traces 34, bonding pads 36 and/or other electrical traces, bonding pads, and circuit elements. Such patterning and etching could be performed using any suitable technique, as would be recognized by one skilled in the art.

Either or both sides of circuit carrier 24 may further be plated or otherwise coated with one or more layers of substantially transparent conductive material, for example, indium tin oxide. This substantially transparent conductive material could be patterned and etched to further form sensing electrodes 16 and/or other sensing electrodes, circuit traces, and the like. This step could yield a layer of substantially transparent conductive material on circuit carrier 24 superimposed upon or underneath at least a portion of sensing electrodes 16 formed in the step described above, including the area corresponding to the apertures therein, thereby effectively increasing the surface area of sensing electrodes 16. Such patterning and etching could be performed using any suitable technique, as would be recognized by one skilled in the art. User interface substrate 12, light guides 26, lighting substrate 28, and/or reflectors 32 can be joined to circuit carrier 24 using any suitable technique.

This disclosure illustrates and describes certain embodiments of a user interface having an integrated sensing electrode and backlight mask. The disclosure is not intended to limit the scope of the present invention, and one skilled in the art would recognize that these embodiments could be modified without departing from the scope of the present invention, which is defined by the following claims.

1. A user interface comprising:
a user interface substrate, said user interface substrate having a front surface and a rear surface;
a touch sensor sensing electrode disposed on said user interface substrate, said sensing electrode comprising a substantially opaque, conductive material, said substantially opaque, conductive material defining an aperture therein;
an electrical circuit trace disposed on said user interface substrate, said electrical circuit trace coupled to said sensing electrode, and
a first light source associated with said sensing electrode, said first light source adapted to project light toward said sensing electrode and through said aperture but not toward portions of said user interface substrate surrounding said sensing electrode, whereby said light is visible at said front surface of said user interface substantially in the form of said aperture;
wherein said sensing electrode is located between said first light source and said front surface of said user interface substrate.

2. The user interface of claim 1 further comprising touch sensor control circuitry disposed on said circuit carrier, said touch sensor control circuitry coupled to said electric circuit trace.

3. The user interface of claim 1 further comprising:
a mask associated with said user interface substrate, said mask comprising a substantially opaque, conductive material, said substantially opaque, conductive material defining an aperture therein; and
a second light source associated with said mask, said mask located between said second light source and said front surface of said user interface substrate;
wherein light emanating from said second light source associated with said mask is visible at said front surface of said user interface substrate in the form of said aperture.

4. The user interface of claim 1, said sensing electrode further comprising a substantially transparent conductive material, said substantially transparent conductive material superimposed with at least said aperture defined by said substantially opaque, conductive material and electrically coupled to said substantially opaque, conductive material.

5. The user interface of claim 1, wherein said light source is electrically coupled to said user interface substrate, said user interface further comprising a reflector associated with said light source and said sensing electrode.

6. A user interface comprising:
a user interface substrate, said user interface substrate having a front surface and a rear surface;
a circuit carrier associated with said rear surface of said user interface substrate;
a touch sensor sensing electrode disposed on said circuit carrier, said sensing electrode comprising a substantially opaque, conductive material, said substantially opaque, conductive material defining an aperture therein; and
a first light source associated with said sensing electrode, said light source adapted to project light toward said sensing electrode and through said aperture but not toward portions of said circuit carrier surrounding said sensing electrode, whereby said light is visible at said front surface of said user interface substantially in the form of said aperture;
wherein said sensing electrode is located between said first light source and said front surface of said user interface substrate.

7. The user interface of claim 6 further comprising an electrical circuit trace disposed on said circuit carrier, said electrical circuit trace coupled to said sensing electrode.

8. The user interface of claim 7 further comprising touch sensor control circuitry disposed on said circuit carrier, said touch sensor control circuitry coupled to said electric circuit trace.

9. The user interface of claim 6, said sensing electrode further comprising a substantially transparent conductive material, said substantially transparent conductive material superimposed with at least said aperture defined by said substantially opaque, conductive material and electrically coupled to said substantially opaque, conductive material.

10. The user interface of claim 6 further comprising a reflector associated with said light source and said sensing electrode.

11. A method of making a user interface, comprising the steps of:
providing a circuit carrier comprising a substantially opaque conductive coating on at least one surface thereof;
patterning and etching said substantially opaque conductive coating to form a sensing electrode, said sensing electrode defining an aperture;
providing a light source in association with said sensing electrode and a first side of said printed wiring board such that indicia in the form of said aperture is visible from a second side of said printed wiring board when said light source is energized.

12. The method of claim 11 wherein said step of patterning and etching further comprises patterning and etching said substantially opaque conductive coating to form at least one electrical circuit trace.

13. The method of claim 11 further comprising the steps of:
providing on said circuit carrier a substantially transparent conductive coating upon or underneath, and electrically coupled to, said substantially opaque conductive coating; and
patterning and etching said substantially transparent conductive coating to further form said sensing electrode.
